(19) United States
(12) Patent Application Publication
(10) Pub. No.: US 2026/0138490 A1
(43) Pub. Date: May 21, 2026

(54) BATTERY SHARING MEDIATION SYSTEM AND METHOD FOR VEHICLE

(71) Applicant: Hyundai Kefico Corporation, Gunpo, Gyeonggi-Do (KR)

(72) Inventors: Se Hee Byun, Seoul (KR); Ho Kyung Kim, Hwaseong, Gyeonggi-do (KR); Nam Chul Paik, Anyang, Gyeonggi-do (KR); In Jae Kwak, Hwaseong, Gyeonggi-do (KR); Hyeong Tae Noh, Gunpo, Gyeonggi-do (KR); Sil Lo Jin, Gunpo, Gyeonggi-do (KR); Sang Hoon Kim, Seoul (KR); Sang Hwan Oh, Hwaseong, Gyeonggi-do (KR); Dae Woo Kim, Gunpo, Gyeonggi-do (KR)

(21) Appl. No.: 18/704,672

(22) PCT Filed: Oct. 20, 2022
(86) PCT No.: PCT/KR2022/016011

§ 371 Date: Apr. 25, 2024

(30) Foreign Application Priority Data
Oct. 25, 2021 (KR) 10-2021-0142461

(51) Int. Cl. B60L 53/80; B60L 50/60; G01R 31/387; G06Q 50/40

(52) U.S. Cl. CPC B60L 53/80; B60L 50/60; G01R 31/387; G06Q 50/40; B60L 2240/62

(57) ABSTRACT

A battery sharing mediation system provides a sharing service for users of electric vehicles equipped with batteries to share batteries with each other and a battery sharing mediation method using the same, and the system includes a plurality of devices configured for users applied for the sharing service to request or accept battery sharing, and a mediation server configured to communicate with the plurality of devices, register and manage service information of the users applied for the sharing service, and mediate the battery sharing between the battery sharing requester and a final sharer selected among the battery sharing candidates, where the sharing information may include an expected transportation conveyance for the battery to be shared.

### CROSS-REFERENCE TO RELATED APPLICATION(S)

The present application is a U.S. National Phase application under 35 U.S.C. § 371 of International Application No. PCT/KR 2022/016011 filed on Oct. 20, 2022, which claims under 35 U.S.C. § 119(a) the benefit of Korean Application No. 10-2021-0142461 filed on Oct. 25, 2021, the entire contents of which are incorporated by reference herein.

### BACKGROUND

### (a) Technical Field

The present disclosure relates to a battery sharing mediation system and method for a vehicle, more particularly, to the battery sharing mediation system that provides a sharing service for users of electric vehicles equipped with batteries to share batteries with each other, and a battery sharing mediation method using the same.

### (b) Description of the Related Art

Electric vehicles are emerging as the mainstream of vehicle technology due to their eco-friendly nature, but there is an inconvenience regarding the longer time required for charging the battery compared to refueling internal combustion engine cars. To address this inconvenience, battery swapping stations operating on an exchange basis could serve as an alternative solution.

A station operating on an exchange basis refers to a station equipped with multiple slots for battery exchange, where vehicles arrive, insert their depleted batteries into empty slots, and withdraw fully charged batteries from the slots. This allows for a reduction in the time required for battery charging.

However, until a sufficient number of these exchange-based stations are installed, infrastructure shortages may hinder the widespread adoption of electric vehicles and could leave users in precarious situations if the batteries deplete during operation before reaching a station.

Hence, there is a need for a solution that enables access to power anytime, anywhere in such situations. One possible solution is to allow electric vehicles to exchange batteries with each other on the road in case of a breakdown due to battery discharge, facilitating continued travel to the destination.

However, in such cases, it is necessary to establish a method that can appropriately mediate between users with the higher battery charge (hereinafter referred to as the “sharer”) and users with the lower battery charge (hereinafter referred to as the “sharing requester”), ensuring the travel convenience of both parties is not compromised.

### SUMMARY

The present disclosure provides a system and method capable of effectively matching sharing requesters and sharers, without compromising the travel convenience of both parties, in cases where a user is in an emergency situation due to insufficient battery charge to reach their destination or a battery exchange station.

In order to accomplish the above objects, a battery sharing mediation system providing a sharing service allowing users of electric vehicles equipped with batteries to share batteries with each other according to an embodiment of the present disclosure includes a plurality of devices configured for users applied for the sharing service to request or accept battery sharing, the plurality of devices comprising a first device receiving sharing request information from a battery sharing requester and a second device receiving sharing information from a battery sharing candidate, and a mediation server configured to communicate with the plurality of devices, register and manage service information of the users applied for the sharing service, and mediate the battery sharing between the battery sharing requester and a final sharer selected among the battery sharing candidates, wherein the sharing information includes an expected transportation conveyance for the battery to be shared.

Here, the sharing request information may include at least one of destination, current location, energy efficiency, installed battery status, or desired battery sharing time of the vehicle of the sharing requester.

Here, the sharing information may include at least one of destination, current location, energy efficiency, installed battery status, or expected arrival time of the vehicle of the sharing candidate.

Here, the mediation server, upon receiving a battery sharing request from the first device of the sharing requester, may search for sharing candidates matching the sharing request information among the vehicles of users applied for the sharing service.

In addition, the mediation server may transmit a battery sharing request notification to the second device of the searched sharing candidates, select the first sharing candidate transmitted an acceptance message via the second device as the primary sharer to receive the sharing information, and select the final sharer by determining whether the primary sharer meets the battery sharing eligibility based on the sharing information.

In addition, the mediation server, based on the expected transportation conveyance included in the sharing information being the vehicle equipped with the battery to be shared, may determine the battery sharing eligibility using the predicted remaining state of charge (SOC) of the battery to be shared when driving to the vehicle of the sharing requester using the expected transportation conveyance.

In addition, the mediation server, based on the expected transportation conveyance included in the sharing information being a separate vehicle without installation of the battery to be shared, may determine the sharing eligibility is met unconditionally.

In addition, the mediation server may transmit a battery sharing request notification to the second device of the sharing candidates, receive sharing information from all the sharing candidates through the second device, transmit the sharing information of sharing candidates meeting the battery sharing eligibility to the first device of the sharing requester, and select the final sharer based on the sharing requester's selection.

In addition, the mediation server may transmit the service information of all the sharing candidates to the first device of the sharing requester, allowing the sharing requester to select the primary sharer, receive the sharing information from the selected primary sharer through the second device, and determine the battery sharing eligibility of the primary sharer to select the final sharer.

In order to accomplish the above objects, a battery sharing mediation method providing a sharing service allowing users of electric vehicles equipped with batteries to share batteries with each other using a mediation server according to an embodiment of the present disclosure includes registering the service information of the users applied for the sharing service, receiving the battery sharing request and sharing request information from the device of a sharing requester requesting for battery sharing, searching for sharing candidates among the users applied for the sharing service based on the sharing request information and selecting and determining a final sharer among the sharing candidates based on the sharing information received from sharing candidates, and mediating between the sharing requester and the final sharer, wherein the sharing information includes an expected transportation conveyance for the battery to be shared.

Here, the sharing request information may include at least one of destination, current location, energy efficiency, installed battery status, or desired battery sharing time of the vehicle of the sharing requester.

Here, the sharing information may include at least one of destination, current location, energy efficiency, installed battery status, or expected arrival time of the vehicle of the sharing candidate.

Meanwhile, the selecting and determining of a final sharer may include transmitting a battery sharing request notification to the device of the sharing candidates, receiving the sharing information from the sharing candidate transmitted an acceptance message first via the device of the sharing candidate as the primary sharer, and selecting the final sharer by determining whether the primary sharer meets the battery sharing eligibility based on the sharing information.

Here, the selecting and determining of a final sharer may include determining, based on the expected transportation conveyance included in the sharing information being the vehicle equipped with the battery to be shared, the battery sharing eligibility using the predicted remaining state of charge (SOC) of the battery to be shared when driving to the vehicle of the sharing requester using the expected transportation conveyance.

In addition, the selecting and determining of a final sharer comprises determining, based on the expected transportation conveyance included in the sharing information being a separate vehicle without installation of the battery to be shared, the sharing eligibility is met unconditionally.

A possible embodiment of selecting and determining of a final sharer may include transmitting a battery sharing request notification to the device of the sharing candidates, receiving the sharing information from all the sharing candidates through the device of the sharing candidates, and transmitting the sharing information of sharing candidates meeting the battery sharing eligibility to the device of the sharing requester to select the final sharer based on the sharing requester's selection.

A possible embodiment of selecting and determining of a final sharer may include transmitting the service information of all the sharing candidates to the device of the sharing requester to select the primary sharer according to the sharing requester's selection, receiving the sharing information from the selected primary sharer through the device, and determining the battery sharing eligibility of the primary sharer to select the final sharer.

The present disclosure is capable of efficiently matching the sharing requester and the sharer without compromising the travel convenience of both party by searching for matching sharing candidates based on the sharing request information received from the sharing requester, and determining the final sharer based on the battery sharing eligibility identified with the shared information received from the sharing candidate, especially the expected transportation conveyance for the battery to be shared.

### BRIEF DESCRIPTION OF THE DRAWINGS

FIG. 1 is a block diagram illustrating a configuration of a battery sharing mediation system according to an embodiment of the present disclosure;

FIGS. 2A and 2B are diagrams illustrating a detailed configuration of each component of FIG. 1;

FIG. 3 is a flowchart illustrating the process of a battery sharing mediation method according to an embodiment of the present disclosure;

FIG. 4 is a flowchart illustrating the detailed flow of the battery sharing request reception step in the mediation method of FIG. 3;

FIG. 5 is a flowchart illustrating the detailed flow of the candidate sharing search and final sharer determination step in the mediation method of FIG. 3 according to the first embodiment;

FIG. 6 is a flowchart illustrating the detailed flow of the candidate sharing search and final sharer determination step in the mediation method of FIG. 3 according to the second embodiment; and

FIG. 7 is a flowchart illustrating the detailed flow of the candidate sharing search and final sharer determination step in the mediation method of FIG. 3 according to the third embodiment.

### DETAILED DESCRIPTION

Hereinafter, an embodiment of the present disclosure will be described in detail with reference to the accompanying drawings.

The present disclosure can be implemented in diverse embodiments with various modifications, as specifically illustrated in the drawings and comprehensively described in the specification. However, such modifications and embodiments are not intended to limit the disclosure and should be construed including all changes, equivalents, and substitutes within the spirit and scope of the disclosure.

In describing the present disclosure, terms such as “first,” “second,” and the like may be used to refer to various components, but it should be understood that these terms are not intended to be limiting. The terms are used only for distinguishing one component from another component. For example, a first element may be referred to as a second element and, similarly, the second element may be referred to as the first element, without departing from the scope of the present disclosure.

The expression “and/or” is used to convey the possibility of including either a combination of multiple related listed items or any one of the related listed items.

When a component is referred to as being “connected to” or “coupled to” another component, it can imply that the two components are directly connected or coupled to each other, but it can also be understood that there may be other components in between them. In contrast, when a component is referred to as being “directly connected to” or “directly coupled to” another component, it can be understood that there is no intermediate component present between them.

The terminology used herein is for the purpose of describing particular embodiments only and is not intended to be limiting of the disclosure. The singular forms are intended to include the plural forms as well unless the context clearly indicates otherwise.

It will be further understood that the terms “comprises” or “has,” when used in this specification, specify the presence of a stated feature, number, step, operation, component, element, or a combination thereof, but they do not preclude the presence or addition of one or more other features, numbers, steps, operations, components, elements, or combinations thereof.

Unless otherwise defined herein, all terms including technical or scientific terms used herein have the same meanings as commonly understood by those skilled in the art to which the present disclosure belongs. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Furthermore, the following embodiments are provided to explain the disclosure more fully to those skilled in the art and may involve exaggerated shapes and sizes of components in the drawings for clearer illustration purposes.

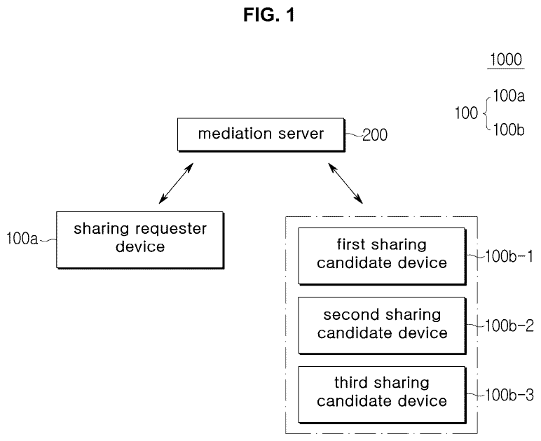

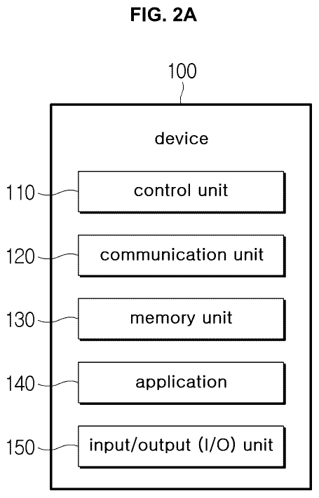

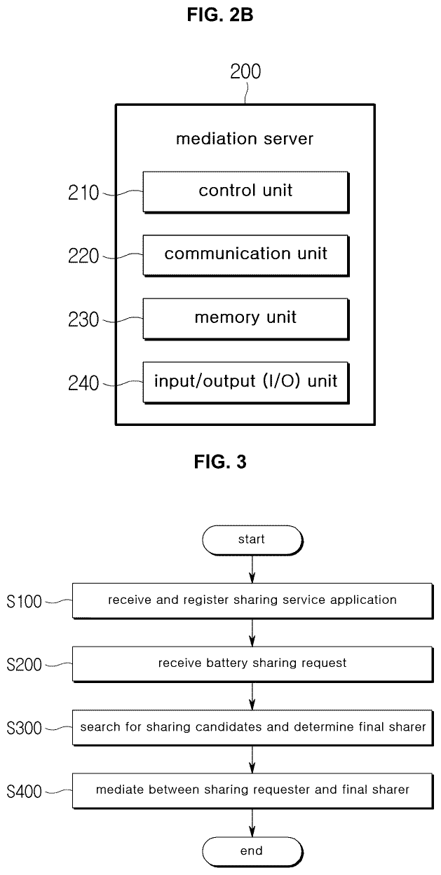

FIG. 1 is a block diagram illustrating a configuration of a battery sharing mediation system according to an embodiment of the present disclosure, and FIGS. 2A and 2B are diagrams illustrating detailed configuration of each component of FIG. 1.

With reference to FIGS. 1, 2A, and 2B, the battery sharing mediation system 1000 according to an embodiment of the present disclosure may include a plurality of devices 100 and a mediation server 200.

The plurality of devices 100 may be configured to allow users who have applied for a sharing service to either request battery sharing or to approve battery sharing.

In this case, the plurality of devices 100 may include a first device 100a receiving sharing request information from the battery sharing requester and a second device 100b receiving sharing information from the battery sharing candidate. Even for the same user, the device 100 may serve as the first device 100a when requesting battery sharing and as the second device 100b when selected as a potential battery sharing candidate.

Users may apply for the sharing service to the mediation server 200, which will be described later, through the device 100.

The service information of users who have applied for the sharing service may be registered and managed by the mediation server 200. The service information may include, for example, subscriber ID, subscriber rating, number of times the battery has been shared, number of times the battery has been received for sharing, current battery state of charge (SOC) and state of health (SOH) information for user vehicles, vehicle energy efficiency, participation in battery sharing, and desired distance for battery sharing, and various other information related to battery sharing services may also be digitized and managed.

The device 100 may be a terminal installed in the vehicle or a portable terminal carried by the user. For example, the device 100 may be a smartphone, tablet personal computer (PC), etc.

In more detail, the device 100 may include a control unit 110, a communication unit 120, a memory unit 130, an input/output (I/O) unit 150, and an application 140.

The control unit 110 may control each component of the device 100. The control unit 110 may be any type of controller capable of executing computer program instructions, such as central processing unit (CPU), microcontroller unit (MCU), microcontroller, or microprocessor.

For example, the control unit 110 may function as a communication module along with the communication unit 120, allowing control over the transmission and reception of information between the mediation server 200. The communication unit is a component capable of communicating with other components via wired and/or wireless means.

For example, the control unit 110 may also function as a memory module along with the memory unit 130, allowing control over retrieving data stored in the memory unit or storing new data. The memory unit 130 may include volatile memory and nonvolatile memory. For example, the memory unit may include at least one of various storage media encompassing semiconductor memory such as random access memory (RAM), read only memory (ROM), and flash memory, magnetic disks, or optical disks. The memory unit 130 may be built into the control unit 110 or installed separately from the control unit 110.

For example, the control unit 110 may also function as an input/output module along with the input/output unit 150, allowing control the input and output of data. The input/output module may perform input/output of various input and output signals. For example, the input/output unit 150 may be configured to receive input from a user via an input/output interface (not shown). The input/output unit 150 may further include an output interface (not shown), such as a display for displaying information.

Alternatively, for example, the control unit 110 may perform part of the battery sharing mediation method along with the application 140. For example, the control unit 110 may request registration of a sharing service with the mediation server 200 through the application 140. Alternatively, for example, the control unit 110 may transmit a battery sharing request or a confirmation of the battery sharing request to the mediation server 200 through the application 140. The control unit 110 may display a battery sharing request notification sent by the mediation server 200 through the application 140.

The mediation server 200 may communicate with the plurality of devices 100.

The mediation server 200 may mediate battery sharing between the battery sharing requester and the final sharer. The final sharer refers to a single user selected as the target of battery sharing mediation from among the battery sharing candidates.

Here, the mediation of battery sharing may be understood as a concept that includes transmitting information on the requester and the final sharer to each other when the battery sharing is finally decided, mediating the location information of the requester and the final sharer in real time until the battery sharing is finally completed, and receiving the final completion status to determine the payment of compensation such as money or points to the final sharer.

The mediation server 200 may include a control unit 210, a communication unit 220, a memory unit 230, and an input/output (I/O) unit 240.

The control unit 210 may control each component of the mediation server 200. The control unit 210 may be any type of controller capable of executing computer program instructions, such as central processing unit (CPU), microcontroller unit (MCU), microcontroller, or microprocessor.

For example, the control unit 210 may function as a communication module along with the communication unit 220 to control the transmission and reception of information between the plurality of devices 100. That is, the mediation server 200 may communicate with each of the plurality of devices 100 through a network.

Alternatively, for example, the control unit 210 may function as a memory module along with the memory unit 230 to control retrieving of data stored in the memory unit 230 or storing of new data. The memory unit 230 may include volatile memory and nonvolatile memory. For example, the memory unit may include at least one of various storage media encompassing semiconductor memory such as random access memory (RAM), read only memory (ROM), and flash memory, magnetic disks, or optical disks. The memory unit 230 may be built into the control unit 210 or installed separately from the control unit 210.

For example, the control unit 210 may also function as an input/output module along with the input/output unit 240, allowing control the input and output of data. The input/output module may perform input/output of various input and output signals. For example, the input/output unit 240 may be configured to receive input from a user via an input/output interface (not shown). The input/output unit 240 may further include an output interface (not shown), such as a display for displaying information.

The mediation server 200 may be configured to operate based on cloud hosting.

A user with a low battery level may become a requester and send a battery sharing request to the mediation server 200.

In the case, the mediation server 200 may receive sharing request information from the requester along with the battery sharing request. The sharing request information may be transmitted through the device of the sharing requester (first device 100a).

The sharing request information may include at least one of the destination, current location, energy efficiency, installed battery status, or desired battery sharing time of the vehicle of the sharing requester.

The mediation server 200 may calculate the SOC of the battery required for the sharing requester to reach the next destination. The necessary SOC for the destination may be calculated based on the remaining distance (Km) from the current location of the sharing requester to the destination and the energy efficiency (kWh/Km) of the vehicle. Calculating the SOC using energy efficiency and distance is a well-known technology in the field, and thus detailed description thereof is omitted herein.

Upon receiving a battery sharing request along with sharing request information from the sharing requester, the mediation server 200 may search for users, or sharing candidates, matching the received sharing request information among the vehicles of users who have applied for the battery sharing service.

In more detail, as matching criteria for sharing candidates, factors such as participation in battery sharing, whether the sharing requester has a battery with SOC charged above the required level, and whether the sharing candidate can reach the current location of sharing requester within the desired time for battery sharing are essential considerations. Additionally, other conditions beyond the above criteria may also be considered for matching candidates.

For example, whether a user has opted for battery sharing participation may be determined using the registered service information of users who have applied for the sharing service.

Meanwhile, all devices 100 of users who have applied for the sharing service may communicate with the vehicle's battery management system (BMS) to receive real-time battery status, which may be transmitted to the mediation server 200. Here, the battery status may refer to SOC or SOH.

Through this, the mediation server 200 may match users who have batteries charged above the SOC required by the sharing requester as sharing candidates.

Additionally, all devices 100 of users who have applied for the sharing service may transmit their own or the vehicle's current location to the mediation server 200 in real-time.

Using this information, the mediation server 200 may match users who can reach the current location of the sharing requester within the desired time for sharing as sharing candidates.

Once sharing candidates are identified by matching the above criteria, the mediation server 200 may send battery sharing request notifications to the devices 100b of the identified sharing candidates.

The sharing candidates receiving the battery sharing request notification may transmit a battery sharing acceptance message to the mediation server 200 via the second device 100b.

In this case, the mediation server 200 may prioritize selecting the sharing candidate who first sends the acceptance message to receive the sharing information. While all sharing candidates receiving the sharing request notification have the right to send the acceptance message, those who attempt to send the acceptance message later may not have their message transmitted to the mediation server 200 until the battery sharing mediation process of the primary sharer fails.

The battery sharing mediation process of the primary sharer fails when the primary sharer is deemed ineligible for battery sharing. The determination on battery sharing eligibility will be described later. Additionally, the primary sharer may cancel the sharing acceptance midway, in which case the battery sharing mediation process also fails.

In a preferred embodiment of the present disclosure, the sharing information transmitted to the mediation server 200 via the second device 100b includes the expected transportation conveyance for the battery to be shared. Additionally, the sharing information may include at least one of the destination, current location, energy efficiency, installed battery status, or expected arrival time of the vehicle of the sharing candidate.

The mediation server 200 may determine whether the primary sharer meets the battery sharing eligibility requirements using the provided sharing information and then select the final sharer.

The battery sharing eligibility may vary depending on the expected transportation conveyance for the shared battery. A detailed description thereof is provided below.

When the expected transportation conveyance specified in the sharing information is the vehicle equipped with the battery to be shared (i.e., when the vehicle equipped with the battery to be shared is the same as the means of transportation), the mediation server 200 may assess the battery sharing eligibility based on the anticipated remaining SOC of the battery to be shared after the associated vehicle reaches the vehicle of the sharing requester.

In this case, the mediation server 200 may calculate the anticipated remaining battery SOC when the vehicle of the primary sharer travels to the current location of the sharing requester based on the energy efficiency of the corresponding vehicle. The mediation server 200 may determine the battery sharing eligibility based on whether the predicted value is equal to or greater than the battery SOC required by the sharing requester.

This allows for consideration of the SOC consumed during travel for battery sharing, thereby enhancing the quality of the sharing service.

Additionally, the mediation server 200 may determine the battery sharing eligibility based on whether the remaining SOC of the sharing requester is sufficient to travel to the next destination of the primary sharer.

This allows for consideration of the convenience of the user sharing the battery, thereby enhancing the quality of the sharing service.

When the expected transportation conveyance is a separate vehicle in which the battery to be shared is not installed (i.e., when the vehicle equipped with the battery to be shared and the transportation conveyance are separate vehicles), the mediation server 200 may assess that the battery sharing eligibility fulfilled without any conditions.

In this case, since the transportation conveyance of the primary sharer is a separate vehicle, the SOC of the battery to be shared is not consumed during the travel of the primary sharer for battery sharing. Hence, there is no requirement to take into account the predicted remaining SOC of either the primary sharer's battery or the sharing requester's battery in this scenario.

In this way, by determining the sharing eligibility in consideration of the transportation conveyance received in the sharing information, it is possible to prevent users who are willing to share the battery from being excluded from the sharing candidates even when they meet the necessary conditions for battery sharing. This helps activate battery sharing services and, furthermore, contributes to resolving issues related to the lack of infrastructure for battery exchange stations.

When the primary sharer fails to meet the battery sharing eligibility, resulting in the failure of the battery sharing mediation process, the sharing candidate who attempted to send the acceptance message in the next priority is selected as the next primary sharer, and undergoes the same process to assess battery sharing eligibility.

The mediation server 200 may repeat this process until the final sharer is determined.

Once the final sharer is determined, the mediation server 200 may transmit the information on the final sharer (including service information and sharing information) to the sharing requester and receive the final decision of the sharing requester regarding whether to proceed with the battery sharing with the determined final sharer.

The mediation server 200 may finally complete the battery sharing by mediating between the selected sharing requester and the final sharer.

Meanwhile, let's designate the scenario, as explained so far, where the sharing candidate who first sends the acceptance message to the mediation server 200 among the searched sharing candidates is selected as the primary sharer, as the first embodiment.

An alternative scenario, referred to as the second embodiment, is as follows.

The mediation server 200 may transmit battery sharing request notifications to the devices of the searched sharing candidates (the second devices 100b) and may receive acceptance messages and sharing information from all sharing candidates through the second devices 100b.

The mediation server 200 may select sharing candidates who meet the battery sharing eligibility from among all sharing candidates who transmitted acceptance messages and sharing information in the previously described manner.

The mediation server 200 may transmit the sharing information of sharing candidates who meet the battery sharing eligibility to the device of the sharing requester (the first device 100a).

The mediation server 200 may select the final sharer among the sharing candidates according to the selection of the sharing requester.

The difference from the first embodiment is that the sharing requester receives the sharing information of all sharing candidates who meet the sharing eligibility instead of a selected primary sharer. This allows the sharing requester to review the sharing information of all eligible candidates and select the final sharer.

Additionally, the sharing requester may receive service information in addition to the sharing information of the sharing candidates. This allows the sharing requester to consider additional factors such as subscriber ratings and sharing frequency when selecting a trustworthy sharing candidate.

An alternative scenario, referred to as the third embodiment, is as follows.

The mediation server 200 may transmit a list containing the service information of all searched sharing candidates to the device of the sharing requester (the first device 100a), and based on the selection of the sharing requester, may select a primary sharer from among the sharing candidates.

The mediation server 200 may then send a battery sharing request notification to the primary sharer selected by the sharing requester and may receive acceptance messages and sharing information to determine battery sharing eligibility. The mediation server 200 may determine the primary sharer as the final sharer when the battery sharing eligibility is met.

When the primary sharer does not send an acceptance message or does not meet the eligibility criteria, the mediation server may resend the list of sharing candidates excluding the primary sharer to the sharing requester and repeat the aforementioned process.

The difference between the first embodiment and the second embodiment lies in providing the sharing requester with a list of sharing candidates who have not undergone battery sharing eligibility assessment, and the primary sharer being determined based on the selection of the sharing requester.

This allows the sharing requester to review the service information provided by the sharing candidates and select the preferred primary sharer. This provides the advantage of prioritizing the preference of the sharing requester even though the decision on the final sharer may take more time as the battery sharing eligibility of the primary sharer is determined later.

On the other hand, since the service information of the sharing candidate is provided first to the sharing requester, the sharing requester can select a more reliable sharing candidate by further referring to the information included in the service information, such as the subscriber rating and the number of shares.

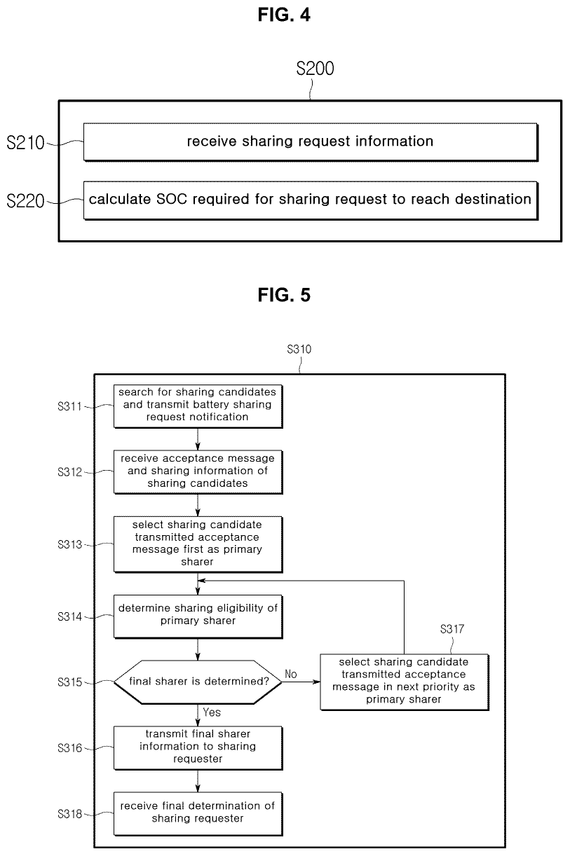

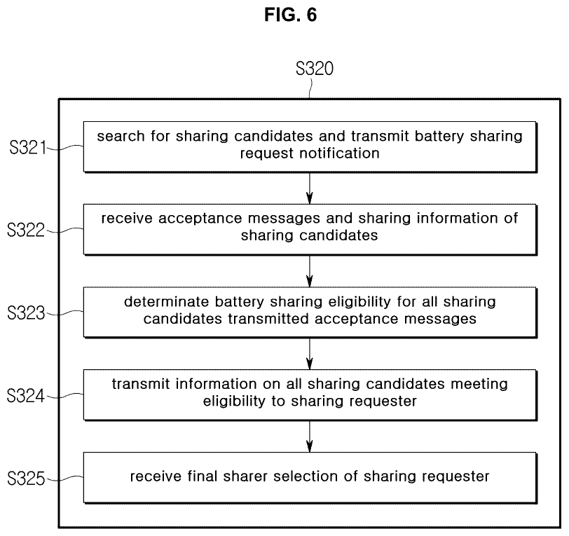

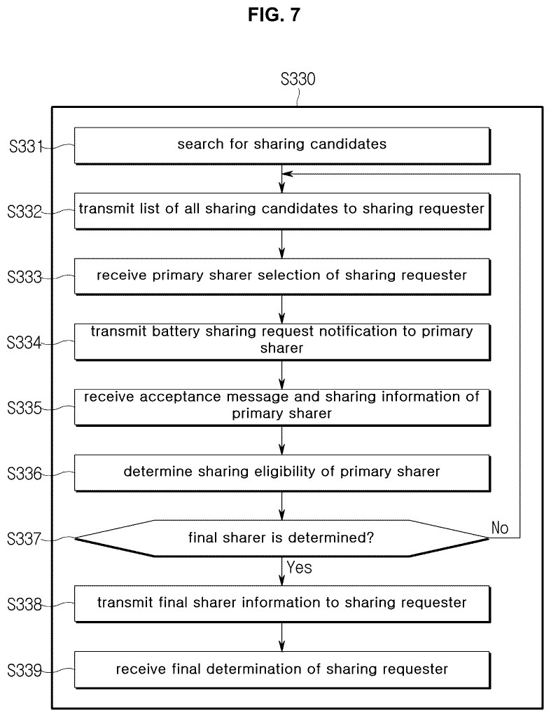

FIG. 3 is a flowchart illustrating the process of a battery sharing mediation method according to an embodiment of the present disclosure, FIG. 4 is a flowchart illustrating the detailed flow of the battery sharing request reception step in the mediation method of FIG. 3, FIG. 5 is a flowchart illustrating the detailed flow of the candidate sharing search and final sharer determination step in the mediation method of FIG. 3 according to the first embodiment, FIG. 6 is a flowchart illustrating the detailed flow of the candidate sharing search and final sharer determination step in the mediation method of FIG. 3 according to the second embodiment, and FIG. 7 is a flowchart illustrating the detailed flow of the candidate sharing search and final sharer determination step in the mediation method of FIG. 3 according to the third embodiment.

The battery sharing mediation method according to an embodiment of the present disclosure may be performed on the above-described mediation server 200.

With reference to FIGS. 3 to 7, the battery sharing mediation method according to an embodiment of the present disclosure may include receiving and registering the sharing service application at step S100, receiving the battery sharing request at step S200, searching for sharing candidates and determining the final sharer at step S300, and mediating between the sharing requester and the final sharer at step S400.

Receiving and registering the sharing service application at step S100 includes receiving requests for the sharing service from users operating electric vehicles and registering service information on the users.

The service information may be registered and managed by the mediation server 200. The service information may include, for example, subscriber ID, subscriber rating, number of times the battery has been shared, number of times the battery has been received for sharing, current SOC and SOH information for user vehicles, vehicle energy efficiency, participation in battery sharing, and desired distance for battery sharing, and various other information related to battery sharing services may also be digitized and managed.

Receiving the battery sharing request at step S200 includes receiving the battery sharing request and sharing request information from the device 100a of the sharing requester requesting the sharing of the battery.

In more detail, the mediation server 200 may receive the sharing request information through the device 100a of the sharing requester at step S210.

The sharing request information may include at least one of the destination, current location, energy efficiency, installed battery status, or desired battery sharing time of the vehicle of the sharing requester.

The mediation server 200 may calculate at step S220 the battery's SOC required for the sharing requester to reach the next destination. The necessary SOC for the battery may be calculated using the remaining distance (Km) to the destination from the current location of the sharing requester and the energy efficiency (kWh/Km) of the vehicle. Calculating the SOC using energy efficiency and distance is a well-known technology in the field, and thus detailed description thereof is omitted herein.

Searching for sharing candidates and determining the final sharer at step S300 includes searching among the users who have applied for the sharing service for sharing candidates that match the sharing request information and selecting and determining the final sharer from among the sharing candidates based on the sharing information received from the sharing candidates.

The first embodiment of step S300 may be performed by the mediation server 200 as denoted by reference number S310 and include the following steps.

The mediation server searches for the sharing candidates based on the sharing request information and transmits battery sharing request notifications to the sharing candidates (S311).

The mediation server receives acceptance message and sharing information from the sharing candidates (S312).

The mediation server selects the sharing candidate that first transmitted the acceptance message as the primary sharer (S313).

The mediation server determines the battery sharing eligibility of the primary sharer (S314).

When the primary sharer meets the battery sharing eligibility, the mediation server determine the primary sharer as the final sharer and transmits the information on the final sharer to the sharing requester. The information on the final sharer may include the registered service information and sharing information of the final sharer (S315 and S317).

When the primary sharer fails to meet the battery sharing eligibility or cancels the acceptance of battery sharing midway, the mediation server determines a battery sharing failure, selects the sharing candidate who sent the acceptance message in the next priority as the primary sharer, and repeats steps S314 and S315 until the final sharer is determined (S315, S316).

The mediation server receives the final decision of the sharing requester regarding whether to proceed with the battery sharing with the determined final sharer (S318).

Meanwhile, the detailed description of the first embodiment of step S300 as denoted by reference number S310 may be replaced with the description of the first embodiment of the battery sharing mediation system 1000.

The second embodiment of step S300 may be performed by the mediation server 200 as denoted by reference number S320 and include the following steps.

The mediation server searches for the sharing candidates based on the sharing request information and transmits battery sharing request notifications to the sharing candidates (S321).

The mediation server receives acceptance message and sharing information from the sharing candidates (S322).

The mediation server determines the battery sharing eligibility for all sharing candidates who have sent acceptance messages (S323).

The mediation server transmits the information on all sharing candidates who meet the battery sharing eligibility to the sharing requester. The information on the sharing candidates may include the registered service information and sharing information of the sharing candidates (S324).

The mediation server receives the final sharer selected by the sharing requester from among the sharing candidates (325).

Meanwhile, the detailed description of the second embodiment of step S300 as denoted by reference number S320 may be replaced with the description of the second embodiment of the battery sharing mediation system 1000.

The third embodiment of step S300 may be performed by the mediation server 200 as denoted by reference number S330 and include the following steps.

The mediation server searches for the sharing candidates based on the sharing request information (S331).

The mediation server transmits the list of all sharing candidates to the sharing requester. The list may include the service information of all sharing candidates (S332).

The mediation server receives the sharing requester's selection of the primary sharer (S333).

The mediation server transmits a battery sharing request notification to the primary sharer (S334).

The mediation server receives acceptance message and sharing information from the primary sharer (S335).

The mediation server determines the battery sharing eligibility of the primary sharer (S336).

When the primary sharer meets the battery sharing eligibility, the mediation server determine the primary sharer as the final sharer and transmits the information on the final sharer to the sharing requester. The information on the final sharer may include the registered service information and sharing information of the final sharer (S337 and S338).

When the primary sharer fails to meet the battery sharing eligibility or cancels the acceptance of battery sharing midway, the mediation server determines a battery sharing failure, retransmits the list of all sharing candidates to the sharing requester, and repeats steps S332 to S337 until the final sharer is determined. In this case, the sharing candidates who have failed in battery sharing are excluded from the list.

The mediation server receives the final decision of the sharing requester regarding whether to proceed with the battery sharing with the determined final sharer (S339).

Meanwhile, the detailed description of the third embodiment of step S300 as denoted by reference number S330 may be replaced with the description of the third embodiment of the battery sharing mediation system 1000.

Mediating the sharing requester and the final sharer at step S400 is a stage where the mediation server 200 mediates between the sharing requester and the determined final sharer and may include transmitting information between the sharing requester and the final sharer, mediating the location information of the sharing requester and the final sharer in real time until the final completion of battery sharing, and receiving the final completion status of battery sharing to determine the payment of compensation, such as money or points, to the final sharer.

As described above, the present disclosure is capable of efficiently matching the sharing requester and the sharer without compromising the travel convenience of both party by searching for matching sharing candidates based on the sharing request information received from the sharing requester, and determining the final sharer based on the battery sharing qualification identified with the shared information received from the sharing candidate, especially the expected transportation conveyance of the battery to be shared.

Meanwhile, although the present disclosure has been described with specific embodiments and drawings, the present disclosure is not limited to the above embodiments, and various modifications and variations can be made from these descriptions by those skilled in the art. Therefore, the technical spirit of the present disclosure should be determined solely by the claims, and all fair or equivalent modifications thereof would be considered within the scope of the technical concept of the present disclosure.

What is claimed is:

1. A battery sharing mediation system providing a sharing service allowing users of electric vehicles equipped with batteries to share batteries with each other, the system comprising:
a plurality of devices configured for users applied for the sharing service to request or accept battery sharing, the plurality of devices comprising a first device receiving sharing request information from a battery sharing requester and a second device receiving sharing information from a battery sharing candidate; and
a mediation server configured to communicate with the plurality of devices, register and manage service information of the users applied for the sharing service, and mediate the battery sharing between the battery sharing requester and a final sharer selected among the battery sharing candidates,
wherein the sharing information comprises an expected transportation conveyance for the battery to be shared.

2. The system of claim 1, wherein the sharing request information comprises at least one of destination, current location, energy efficiency, installed battery status, or desired battery sharing time of the vehicle of the sharing requester.

3. The system of claim 1, wherein the sharing information comprises at least one of destination, current location, energy efficiency, installed battery status, or expected arrival time of the vehicle of the sharing candidate.

4. The system of claim 1, wherein the mediation server, upon receiving a battery sharing request from the first device of the sharing requester, searches for sharing candidates matching the sharing request information among the vehicles of users applied for the sharing service.

5. The system of claim 1, wherein the mediation server transmits a battery sharing request notification to the second device of the sharing candidates, selects the first sharing candidate transmitted an acceptance message via the second device as the primary sharer to receive the sharing information, and selects the final sharer by determining whether the primary sharer meets the battery sharing eligibility based on the sharing information.

6. The system of claim 5, wherein the mediation server, based on the expected transportation conveyance included in the sharing information being the vehicle equipped with the battery to be shared, determines the battery sharing eligibility using the predicted remaining state of charge (SOC) of the battery to be shared when driving to the vehicle of the sharing requester using the expected transportation conveyance.

7. The system of claim 5, wherein the mediation server, based on the expected transportation conveyance included in the sharing information being a separate vehicle without installation of the battery to be shared, determines the sharing eligibility is met unconditionally.

8. The system of claim 4, wherein the mediation server transmits a battery sharing request notification to the second device of the sharing candidates, receives sharing information from all the sharing candidates through the second device, transmits the sharing information of sharing candidates meeting the battery sharing eligibility to the first device of the sharing requester, and selects the final sharer based on the sharing requester's selection.

9. The system of claim 4, wherein the mediation server transmits the service information of all the searched sharing candidates to the first device of the sharing requester, allowing the sharing requester to select the primary sharer, receives the sharing information from the selected primary sharer through the second device, and determines the battery sharing eligibility of the primary sharer to select the final sharer.

10. A battery sharing mediation method providing a sharing service allowing users of electric vehicles equipped with batteries to share batteries with each other using a mediation server, the method comprising:
registering the service information of the users applied for the sharing service;
receiving the battery sharing request and sharing request information from the device of a sharing requester requesting for battery sharing;
searching for sharing candidates among the users applied for the sharing service based on the sharing request information and selecting and determining a final sharer among the sharing candidates based on the sharing information received from sharing candidates;
mediating between the sharing requester and the final sharer,
wherein the sharing information comprises an expected transportation conveyance for the battery to be shared.

11. The method of claim 10, wherein the sharing request information comprises at least one of destination, current location, energy efficiency, installed battery status, or desired battery sharing time of the vehicle of the sharing requester.

12. The method of claim 10, wherein the sharing information comprises at least one of destination, current location, energy efficiency, installed battery status, or expected arrival time of the vehicle of the sharing candidate.

13. The method of claim 10, wherein the selecting and determining of a final sharer comprises:
transmitting a battery sharing request notification to the device of the sharing candidates;
receiving the sharing information from the sharing candidate transmitted an acceptance message first via the device of the sharing candidate as the primary sharer; and
selecting the final sharer by determining whether the primary sharer meets the battery sharing eligibility based on the sharing information.

14. The method of claim 13, wherein the selecting and determining of a final sharer comprises determining, based on the expected transportation conveyance included in the sharing information being the vehicle equipped with the battery to be shared, the battery sharing eligibility using the predicted remaining state of charge (SOC) of the battery to be shared when driving to the vehicle of the sharing requester using the expected transportation conveyance.

15. The method of claim 13, wherein the selecting and determining of a final sharer comprises determining, based on the expected transportation conveyance included in the sharing information being a separate vehicle without installation of the battery to be shared, the sharing eligibility is met unconditionally.

16. The method of claim 10, wherein the selecting and determining of a final sharer comprises:
transmitting a battery sharing request notification to the device of the sharing candidates;
receiving the sharing information from all the sharing candidates through the device of the sharing candidates; and
transmitting the sharing information of sharing candidates meeting the battery sharing eligibility to the device of the sharing requester to select the final sharer based on the sharing requester's selection.

17. The method of claim 10, wherein the selecting and determining of a final sharer comprises:
transmitting the service information of all the sharing candidates to the device of the sharing requester to select the primary sharer according to the sharing requester's selection;
receiving the sharing information from the selected primary sharer through the device; and
determining the battery sharing eligibility of the primary sharer to select the final sharer.
